(19) United States
(12) Patent Application Publication
(10) Pub. No.: US 2025/0221208 A1
(43) Pub. Date: Jul. 3, 2025

(54) DISPLAY PANEL AND DISPLAY DEVICE INCLUDING THE SAME

(71) Applicant: LG DISPLAY CO., LTD., Seoul (KR)

(72) Inventors: Jae Hyung JO, Paju-si (KR); Won Doo KIM, Paju-si (KR)

(73) Assignee: LG DISPLAY CO., LTD., Seoul (KR)

(21) Appl. No.: 18/948,194

(22) Filed: Nov. 14, 2024

(30) Foreign Application Priority Data
Dec. 28, 2023 (KR) 10-2023-0194512

(51) Int. Cl. H10K 59/131; H10K 59/35

(52) U.S. Cl. CPC H10K 59/131; H10K 59/353

(57) ABSTRACT

In a display panel, each of first and second pixels may include a first sub-pixel, a second sub-pixel, and a third sub-pixel having different colors. The first and second pixels may share a white sub-pixel. Each first sub-pixel may include a first pixel circuit and a first light emission area connected to the first pixel circuit. Each second sub-pixel may include a second pixel circuit and a second light emission area connected to the second pixel circuit. Each third sub-pixel may include a third pixel circuit and a third light emission area connected to the third pixel circuit. The white sub-pixel may include a fourth pixel circuit and a fourth light emission area connected to the fourth pixel circuit and may be disposed between the third sub-pixels of the first and second pixels. A display device including a display panel is also disclosed.

### CROSS-REFERENCE TO RELATED APPLICATIONS

This application claims the benefit of and priority to Korean Patent Application No. 10-2023-0194512, filed Dec. 28, 2023, the entire contents of which are incorporated herein by reference for all purposes.

### BACKGROUND

### 1. Technical Field

The present disclosure relates to a display panel and a display device including the same.

### 2. Discussion of the Related Art

An organic light-emitting display device may include an organic light-emitting diode (hereinafter, referred to as “OLED”) that emits light by itself, and has advantages of fast response speed and high luminous efficiency, luminance, and viewing angle. An organic light-emitting display device has an excellent contrast ratio and color reproduction rate because it has a fast response speed and excellent luminous efficiency, luminance, viewing angle, and the like, and may express black grayscale in complete black.

Various studies are being conducted to secure the aperture ratio of the organic light-emitting display device, but it is difficult to design an aperture ratio improvement because there are many wires required for driving pixels. Moreover, when each of the pixels is composed of four colors including red, green, blue, and white, it is more difficult to secure an aperture ratio.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have developed a new invention. One or more aspects of the present disclosure are directed to a display panel and a display device that address the limitations, needs and/or disadvantages of the related art.

In one or more aspects, the present disclosure provides a display panel that may improve the aperture ratio and facilitate a repair process, and a display device including the same.

The aspects and objects of the present disclosure are not limited to the above-mentioned aspects and objects, and other aspects and objects not mentioned will be clearly understood by those skilled in the art from the present disclosure.

A display panel according to one or more example embodiments of the present disclosure includes a first pixel and a second pixel adjacent to each other in a first direction. Each of the first pixel and the second pixel includes a first sub-pixel, a second sub-pixel, and a third sub-pixel configured to emit light having different colors. The first pixel and the second pixel share a white sub-pixel. Each of the first sub-pixels includes a first pixel circuit and a first light emission area connected to the first pixel circuit. Each of the second sub-pixels includes a second pixel circuit and a second light emission area connected to the second pixel circuit. Each of the third sub-pixels includes a third pixel circuit and a third light emission area connected to the third pixel circuit. The white sub-pixel includes a fourth pixel circuit and a fourth light emission area connected to the fourth pixel circuit. The white sub-pixel is disposed between the third sub-pixel of the first pixel and the third sub-pixel of the second pixel in the first direction.

The first, second and third light emission areas of the first pixel and the first, second and third light emission areas of the second pixel may be respectively arranged in mirror symmetry. The third light emission areas of the first pixel and the second pixel may surround top, left, and right sides of the fourth light emission area. The first light emission areas of third and fourth pixels positioned below the first and second pixels may be disposed below the fourth light emission area.

The display panel may further include power lines configured to supply one or more constant voltages to the first, second, third and fourth pixel circuits. The power lines are disposed along a second direction crossing the first direction to overlap the first light emission area, the second light emission area, and the third light emission area.

The power lines may include a first power line to which a pixel driving voltage is for being applied; and second power lines disposed on both sides of the first power line and connected to each other. A width of the first power line may be greater than a width of each of the second power lines.

The display panel may further include a plurality of data line pairs configured to supply data voltages of pixel data to the first, second, third and fourth pixel circuits. The plurality of data line pairs may include a first data line pair and a second data line pair. The first data line pair may include a first data line connected to a plurality of first pixel circuits arranged along the second direction; and a second data line connected to a plurality of second pixel circuits arranged along the second direction. The second data line pair may include a third data line connected to a plurality of third pixel circuits arranged along the second direction; and a fourth data line connected to a plurality of fourth pixel circuits arranged along the second direction.

The second data line pair may overlap the fourth light emission area.

The display panel may further include a plurality of gate lines disposed along the first direction. The two gate lines disposed with two light emission areas having different colors interposed therebetween are connected to each other. In this regard, in one or more examples, the two light emission areas, among the first, second and third light emission areas and the fourth light emission area of the first and second pixels, may be configured to emit light having different colors. The two light emission areas may be disposed between the two gate lines among the plurality of gate lines. The two gate lines may be connected to each other.

The fourth pixel circuit may include a fourth-1 pixel circuit connected to the fourth light emission area; and a fourth-2 pixel circuit connected to the fourth light emission area.

The fourth-1 pixel circuit and the fourth-2 pixel circuit may be connected to different gate lines to sequentially receive gate pulses.

The fourth light emission area may include a fourth-1 light emission area connected to the fourth-1 pixel circuit; and a fourth-2 light emission area separated from the fourth-1 light emission area and connected to the fourth-2 pixel circuit.

The display panel may further include a repair pattern overlapping the pixel circuits between the sub-pixels (or within a sub-pixel) of the same color adjacent to each other in the first direction with an insulating layer interposed therebetween. The repair pattern may be selectively electrically connected to the pixel circuits between the sub-pixels of the same color. In this regard, in one or more examples, the display panel may include: a plurality of sub-pixels; a plurality of pixel circuits; and a repair pattern. The plurality of sub-pixels may include the first, second and third sub-pixels of the first and second pixels and the white sub-pixel. The plurality of pixel circuits may include the first, second and third pixel circuits of the first and second pixels and the fourth pixel circuit. Adjacent pixel circuits of a same color may be pixel circuits among the plurality of pixel circuits, where the pixel circuits are configured to emit light having the same color and are disposed adjacent to each other in the first direction. The adjacent pixel circuits of the same color may be disposed between adjacent sub-pixels among the plurality of sub-pixels or may be disposed within a sub-pixel among the plurality of sub-pixels. The repair pattern may overlap the adjacent pixel circuits of the same color. An insulating layer may be interposed between the repair pattern and the adjacent pixel circuits of the same color. The repair pattern may be for being selectively electrically connected to the adjacent pixel circuits of the same color.

The first sub-pixel may be a blue sub-pixel. The second sub-pixel may be a green sub-pixel. The third sub-pixel may be a red sub-pixel.

A display device according to one or more example embodiments of the present disclosure includes: a display panel in which a plurality of data lines, a plurality of gate lines, a plurality of power lines, and a plurality of pixels are arranged; a data driver configured to convert pixel data into data voltages and to supply the data voltages to the plurality of data lines; a gate driver configured to sequentially supply gate pulses to the plurality of gate lines; and a timing controller configured to transmit the pixel data to the data driver and to control the data driver and the gate driver. The display panel includes a first pixel and a second pixel adjacent to each other in a first direction. Each of the first pixel and the second pixel includes a first sub-pixel, a second sub-pixel, and a third sub-pixel configured to emit light having different colors. The first pixel and the second pixel share a white sub-pixel. Each of the first sub-pixels includes a first pixel circuit and a first light emission area connected to the first pixel circuit. Each of the second sub-pixels includes a second pixel circuit and a second light emission area connected to the second pixel circuit. Each of the third sub-pixels includes a third pixel circuit and a third light emission area connected to the third pixel circuit. The white sub-pixel includes a fourth pixel circuit and a fourth light emission area connected to the fourth pixel circuit. The white sub-pixel is disposed between the third sub-pixel of the first pixel and the third sub-pixel of the second pixel in the first direction.

When the display device drives the first pixel with four sub-pixels including the first sub-pixel of the first pixel, the second sub-pixel of the first pixel, the third sub-pixel of the first pixel, and the white sub-pixel, the display device may drive the second pixel with three sub-pixels including the first sub-pixel of the second pixel, the second sub-pixel of the second pixel, and the third sub-pixel of the second pixel. When the display device drives the second pixel with four sub-pixels including the first sub-pixel of the second pixel, the second sub-pixel of the second pixel, the third sub-pixel of the second pixel, and the white sub-pixel, the display device may drive the first pixel with three sub-pixels including the first sub-pixel of the first pixel, the second sub-pixel of the first pixel, and the third sub-pixel of the first pixel.

During an odd-numbered frame period, the display device may drive the first pixel with the four sub-pixels of the first pixel and the second pixel with the three sub-pixels of the second pixel at the same time. During an even-numbered frame period, the display device may drive the second pixel with the four sub-pixels of the second pixel and the first pixel with the three sub-pixels of the first pixel at the same time.

In a mode, the fourth light emission area may be configured to emit light with a luminance of a decimal grayscale value, to provide luminances of the fourth-1 and fourth-2 light emission areas that are different from each other.

The first pixel and the second pixel may be simultaneously driven with the three sub-pixels when the input image is a pure color or a saturation of the input image is greater than or equal to a preset reference value. In this regard, in one or more examples, the display device may be configured to simultaneously drive the first and second pixels with a set of sub-pixels, in response to an input image being a pure color or a saturation of the input image being greater than or equal to a preset reference value. The set of sub-pixels may include the first sub-pixel of the first pixel, the second sub-pixel of the first pixel, the third sub-pixel of the first pixel, the first sub-pixel of the second pixel, the second sub-pixel of the second pixel, and the third sub-pixel of the second pixel.

The third light emission areas of the first pixel and the second pixel may surround first, second and third sides of the fourth light emission area. One side of a first pixel circuit of a third pixel may face a side of the fourth light emission area without having a light emission area disposed between the one side and the side. The first side may extend along the first direction. Each of the second and third sides may extend along a second direction different from the first direction. Each of the one side and the side may extend along the second direction.

The first light emission areas of the first and second pixels may be configured to emit light having a same first color and are disposed adjacent to each other without a light emission area disposed between the first light emission areas. The second light emission areas of the first and second pixels may be configured to emit light having a same second color and are disposed adjacent to each other without a light emission area disposed between the second light emission areas. The fourth light emission area configured to emit light having another color is not adjacent to another light emission area configured to emit light having the same another color.

According to one or more aspects of the present disclosure, high efficiency and high luminance pixel driving is possible by using four sub-pixel driving, so that the display panel may be driven at low power.

In one or more aspects, the present disclosure may provide a display panel capable of improving the aperture ratio, facilitating repair design, and optimizing a process.

According to one or more aspects of the present disclosure, since the light emission area generating white light is not continuous, an image may be reproduced on the display panel without a white horizontal line pattern or a vertical line pattern, thereby improving display quality.

According to one or more aspects of the present disclosure, neighboring pixels may alternately drive four sub-pixels and three sub-pixels to increase the luminance of an image reproduced on the display panel and improve the color reproduction rate.

According to one or more aspects of the present disclosure, a light emission area of a white sub-pixel may be enlarged without bending a wire pattern.

According to one or more aspects of the present disclosure, pixel circuits for driving sub-pixels of the same color are adjacent left and right in the horizontal direction without a light emission area therebetween, so there is minimal decrease in the aperture ratio due to the repair pattern disposed therebetween.

The effects of the present disclosure are not limited to those mentioned above, and other effects not mentioned will be clearly understood by those skilled in the art from the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a block diagram illustrating a display device according to one example embodiment of the present disclosure;

FIG. 2 is a diagram illustrating a pixel configuration according to one example embodiment of the present disclosure;

FIG. 3 is an equivalent circuit diagram illustrating in detail one example of the pixel circuits illustrated in FIG. 2;

FIG. 4 is a circuit diagram illustrating one example of a unit pixel circuit;

FIG. 5 is an example of a diagram illustrating a light emission area of 2×2 pixels;

FIGS. 6, 7A, 7B, 8 and 9 are diagrams illustrating examples of a hybrid driving method;

FIGS. 10A, 10B, 11A, 11B, 12A, 12B, 13A and 13B are examples of diagrams sequentially illustrating a driving sequence of pixels shown in FIG. 2 in units of one horizontal period;

FIG. 14 is a waveform diagram illustrating one example in which gate pulses are alternated;

FIGS. 15 and 16 are diagrams illustrating pixel configurations according to other example embodiments of the present disclosure;

FIGS. 17A to 17E are diagrams illustrating examples of a method of controlling luminance of a white sub-pixel when the luminance is independently controlled in the first and second light emission areas of the white sub-pixel;

FIGS. 18A and 18B are examples of diagrams illustrating paths in which a constant voltage required for pixel driving is applied to pixels;

FIGS. 19A and 19B are diagrams illustrating examples in which the size of a light emission area changes without changing the wire of a display panel;

FIG. 20 is a diagram illustrating one example of a repair pattern according to one example embodiment of the present disclosure;

FIG. 21 is an example of an enlarged view showing part A shown in FIG. 20 in detail;

FIG. 22 is a circuit diagram showing one example of a part(s) to be cut and a part(s) to be welded in a repair process;

FIG. 23 is a cross-sectional view showing one example of a laser cutting method; and

FIG. 24 is a cross-sectional view showing one example of a laser welding method.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, lines, sub-pixels, circuits, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, lines, sub-pixels, circuits, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate (ly),” or “direct (ly),” is used.

It is understood that, although the terms “first,” “second,” “(4-1)th,” “(4-2)th,” “fourth-1,” “fourth-2,” and the like may be used herein to describe various elements (e.g., layers, films, components, lines, sub-pixels, circuits, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, the (4-1)th element, the (4-2)th element, the fourth-1 element, the fourth-2 element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, component, line, sub-pixel, circuit, region, area, portion, or the like) is “crossing,” “intersecting,” “connected,” “coupled,” “attached,” “adhered,” “linked,” or the like another element or to another element, the element can not only be directly crossing, intersecting, connected, coupled, attached, adhered, linked, or the like another element or to another element, but also be indirectly crossing, intersecting, connected, coupled, attached, adhered, linked, or the like another element or to another element with one or more intervening elements disposed or interposed between the elements, unless otherwise specified.

For the expression that an element (e.g., layer, film, component, line, sub-pixel, circuit, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, component, line, sub-pixel, circuit, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, component, line, sub-pixel, circuit, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, line, sub-pixel, circuit, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “nth” may refer to “nnd” (e.g., 2nd where n is 2), or “nrd” (e.g., 3rd where n is 3), and n may be a natural number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

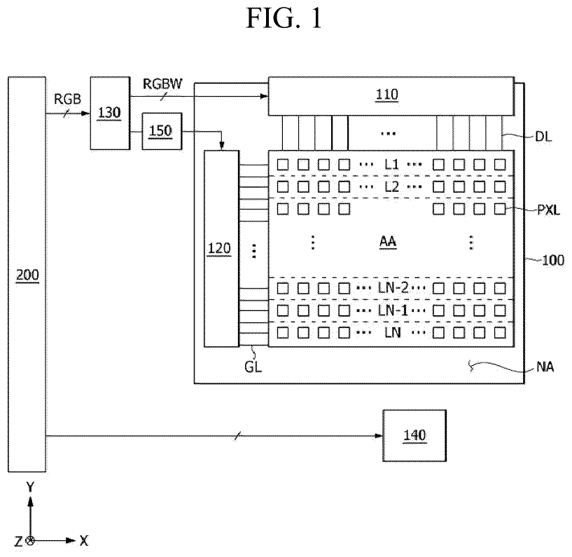

FIG. 1 is a block diagram illustrating a display device according to one example embodiment of the present disclosure.

Referring to FIG. 1, a display device according to an example embodiment of the present disclosure includes a display panel 100, a display panel driving circuit for writing pixel data to pixels of the display panel 100, and a power supply 140 that generates power necessary for driving the pixels and the display panel driving circuit.

The display panel 100 may be a panel having a rectangular structure having a length in an X-axis direction (or a first direction), a width in a Y-axis direction (or a second direction), and a thickness in a Z-axis direction (or a third direction). The X-axis and the Y-axis may be linear axes orthogonal to each other on the XY plane. The display area AA of the display panel 100 includes a pixel array displaying an input image. The pixel array includes a plurality of data lines DL, a plurality of gate lines GL intersecting the data lines DL, and pixels arranged in a matrix form. The display panel 100 includes power lines commonly connected to the pixels. The power lines are connected to constant voltage nodes of the pixel circuits so as to supply a constant voltage required for driving the pixels PXL to the pixels PXL. The power lines may be implemented as stripe or mesh wires to be commonly connected to pixels of the display panel 100.

Each of the pixels PXL includes, for color implementation, a first sub-pixel, a second sub-pixel, a third sub-pixel, and a fourth sub-pixel having different colors. In this example, the first sub-pixel, the second sub-pixel, the third sub-pixel, and the fourth sub-pixel are configured to emit light having different colors. The color arrangement of the sub-pixels may be changed. The first sub-pixel may be a blue (B) sub-pixel, the second sub-pixel may be a green (G) sub-pixel, the third sub-pixel may be a red (R) sub-pixel, and the fourth sub-pixel may be a white (W) sub-pixel, but is not limited thereto. Each of the sub-pixels includes a pixel circuit for driving a light-emitting element. Each of the pixel circuits is connected to data lines, gate lines, and power lines. Each of the sub-pixels may be divided into a circuit area and a light emission area. The pixel circuit is disposed in the circuit area. The light emission area is an area in which light of the light-emitting element electrically connected to the pixel circuit is emitted.

The pixel array includes a plurality of pixel lines L1 to LN. Each of the pixel lines L1 to LN includes one line of pixels disposed along the line direction (X-axis direction) in the pixel array of the display panel 100. Pixels disposed in one pixel line share the gate lines GL. Pixels disposed in the column direction Y along the data line direction share the same data line DL. One horizontal period is a time obtained by dividing one frame period by the total number of pixel lines L1 to LN.

The power supply 140 outputs the voltages required to drive the pixels of the display panel 100 and the display panel driving circuit using a DC-DC converter. The DC-DC converter may include a charge pump, a regulator, a buck converter, a boost converter, and the like.

The display panel driving circuit writes pixel data of the input image to pixels of the display panel 100 under the control of a timing controller 130. The display panel driving circuit includes a data driver 110 and a gate driver 120.

The display panel driving circuit may drive pixels through double rate driving (DRD). In a display panel driven by DRD, data lines DL are connected to neighboring sub-pixels in left and right directions so that the number of channels of the data driver 110 and the number of data lines DL are reduced, which is advantageous in securing an aperture ratio of the pixels.

The display panel driving circuit may further include a touch sensor driver for driving touch sensors. The touch sensor driver is omitted from FIG. 1. The data driver 110 and the touch sensor driver may be integrated together in a single source drive integrated circuit (IC).

The data driver 110 receives the pixel data of the input image received as the digital signal from the timing controller 130 and outputs the data voltage. The data driver 110 converts the pixel data of the input image into a gamma compensation voltage for each frame period using a digital to analog converter (DAC) to output the data voltage. The data voltage is output from each of the channels of the data driver 110 through the output buffer.

The gate driver 120 may be formed in the display panel 100 together with the TFT array of the pixel array and the wires. The gate driver 120 may be disposed in the non-display area NA of the display panel 100, or at least a portion thereof may be disposed in the display area AA in which the input image is reproduced.

The gate driver 120 may be disposed in both non-display areas NA of the display panel 100 with the display area AA of the display panel 100 interposed therebetween to supply gate pulses to both sides of the gate lines GL in a double feeding manner. In another embodiment, the gate driver 120 may be disposed on one side of the left and right non-display areas NA of the display panel 100 to supply gate signals to the gate lines GL in a single feeding manner. The gate driver 120 sequentially outputs pulses of the gate signals (hereinafter, referred to as “gate pulses”) to the gate lines under the control of the timing controller 130. The gate driver 120 may sequentially supply the signals to the gate lines GL by shifting the gate pulses using a shift register. The gate driver 120 may include one or more shift registers outputting pulses of the gate signals.

The timing controller 130 receives digital video data of an input image and a timing signal synchronized with the data from the host system 200. The timing signal may include a vertical synchronization signal, a horizontal synchronization signal, a clock, a data enable signal, and the like. Since the vertical period and the horizontal period may be known by a method of counting the data enable signal, the vertical synchronization signal and the horizontal synchronization signal may be omitted. The data enable signal has an interval of one horizontal period (1H). The timing controller 130 generates a data timing control signal for controlling the operation timing of the data driver 110 and a gate timing control signal for controlling the operation timing of the gate driver 120, based on the timing signal received from the host system 200.

The timing controller 130 may add white data to the three primary color pixel data RGB inputted from the host system, convert the same into four-color sub-color data RGBW, and transmit the same to the data driver 110. A method of converting the three primary color pixel data RGB into four-color sub-color data RGBW including the white data may use a known color conversion algorithm. For example, the timing controller 130 may generate the W data of the first pixel data based on the minimum grayscale value among the R data, G data, and B data of the first pixel data received as the data of the input image, and convert the first pixel data into the four-color sub-color data RGBW. Also, the timing controller 130 may generate the W data of the second pixel data based on the minimum grayscale value among the R data, G data, and B data of the second pixel data received as the data of the input image, and convert the second pixel data into the four-color sub-color data RGBW. In each of the first and second pixel data, the grayscale values of the R, G, and B data may be lowered as much as the W data. Here, R data is data to be written in a red sub-pixel, and G data is data to be written in a green sub-pixel. B data is data to be written in a blue sub-pixel, and W data is data to be written in a white sub-pixel.

The level shifter 150 may receive a gate timing control signal from the timing controller 130 to generate a start pulse and a shift clock and provide the same to the gate driver 120. The start pulse and the shift clock output from the level shifter 150 swing between the gate high voltage and the gate low voltage.

The host system 200 may include a main board of any one of a television (TV) system, a set-top box, a navigation system, a personal computer (PC), a vehicle system, a mobile terminal, and a wearable terminal. The host system may scale the image signal from the video source to match the resolution of the display panel 100 and transmit the same to the timing controller 130 together with the timing signal.

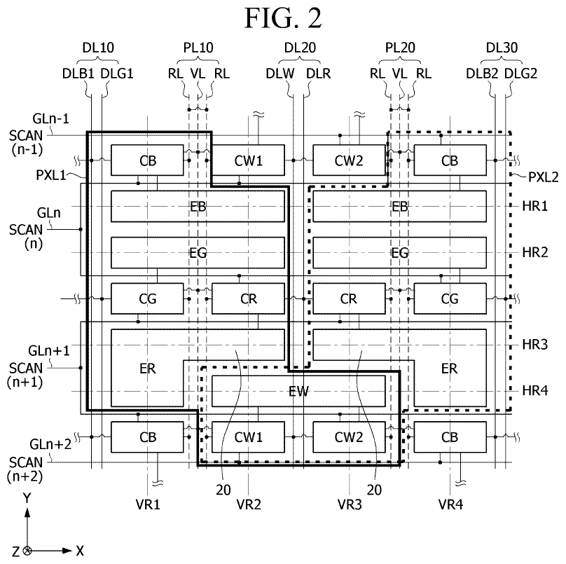

FIG. 2 is a diagram schematically illustrating first and second pixels according to one example embodiment of the present disclosure. The pixels of the display panel may be arranged in a form in which structures of the first and second pixels are repeated.

Referring to FIG. 2, the display panel 100 includes at least first and second pixels PXL1 and PXL2. The first and second pixels PXL1 and PXL2 may be disposed in a left-right mirror symmetrical structure with respect to a Y axis.

The display panel 100 includes a first data line pair DL10 consisted of data lines DLB1 and DLG1 parallel to the Y-axis direction on the left side of the first pixel PXL1, a second data line pair DL20 consisted of data lines DLW and DLR parallel to the Y-axis direction at a boundary between the first pixel PXL1 and the second pixel PXL2, a third data line pair DL30 consisted of data lines DLB2 and DLG2 parallel to the Y-axis direction on the right side of the second pixel PXL2, first power lines PL10 consisted of power lines VL and RL parallel to the Y-axis direction between the first data line pair DL10 and the second data line pair DL20, and second power lines PL20 consisted of power lines VL and RL parallel to the Y-axis direction between the second data line pair DL20 and the third data line pair DL30.

In FIG. 2, the first vertical reference line VR1 is a virtual line parallel to the Y-axis direction between the first data line pair DL10 and the first power lines PL10. The second vertical reference line VR2 is a virtual line parallel to the Y-axis direction between the first power lines PL10 and the second data line pair DL20. The third vertical reference line VR3 is a virtual line parallel to the Y-axis direction between the second data line pair DL20 and the second power lines PL20. The fourth vertical reference line VR4 is a virtual line parallel to the Y-axis direction between the second power lines PL20 and the third data line pair DL30.

The first pixel PXL1 includes a blue sub-pixel, a green sub-pixel, and a red sub-pixel disposed along the Y-axis direction to pass through the virtual first and second vertical reference lines VR1 and VR2. The second pixel PXL2 includes a blue sub-pixel, a green sub-pixel, and a red sub-pixel disposed along the Y-axis direction to pass through the virtual third and fourth vertical reference lines VR3 and VR4. A blue sub-pixel, a green sub-pixel, and a red sub-pixel are separated from each other between the first and second pixels PXL1 and PXL2. Independent R, G, and B data are written to the first and second pixels PXL1 and PXL2.

The first and second pixels PXL1 and PXL2 share a single white sub-pixel. The light emission area EW of the white sub-pixel includes an area where the second and third vertical reference lines VR2 and VR3 intersect with the virtual fourth horizontal reference line HR4.

Each of the first and second pixels PXL1 and PXL2 may be driven by four sub-pixels or three sub-pixels. The four sub-pixels include a red sub-pixel, a green sub-pixel, a blue sub-pixel, and a shared white sub-pixel. The three sub-pixels include a red sub-pixel, a green sub-pixel, and a blue sub-pixel excluding the white sub-pixel.

When the first pixel PXL1 is driven with four sub-pixels, W data generated from R, G, and B data of the first pixel PXL1 are written to the white sub-pixel. When the second pixel PXL2 is driven with four sub-pixels, W data generated from R, G, and B data of the second pixel PXL2 are written to the white sub-pixel.

The first and second pixels PXL1 and PXL2 may be driven by a hybrid method. For example, when the first pixel PXL1 is driven with four sub-pixels, the second pixel PXL2 may be driven with three sub-pixels. When the second pixel PXL2 is driven with four sub-pixels, the first pixel PXL1 may be driven with three sub-pixels.

The timing controller 130 may simultaneously drive the pixels PXL1 and PXL2 with three sub-pixels when the input image is a pure color or the saturation of the input image is greater than or equal to a predetermined reference value by analyzing the saturation of the input image. In this case, the white sub-pixel may be not driven.

The blue sub-pixel includes a first pixel circuit CB and a first light emission area EB connected to the first pixel circuit CB to emit blue light. The green sub-pixel includes a second pixel circuit CG and a second light emission area EG connected to the second pixel circuit CG to emit green light. The red sub-pixel includes a third pixel circuit CR and a third light emission area ER connected to the third pixel circuit CR to emit red light. The white sub-pixel includes a fourth pixel circuit CW1 and CW2 and a fourth light emission area EW connected to the fourth pixel circuit CW1 and CW2 to emit white light. An anode electrode of a light-emitting element EL may be disposed in each of the light emission areas EB, EG, ER, and EW. The pixel circuits CB, CG, CR, CW1, and CW2 are connected to anode electrodes of light-emitting elements in their corresponding light emission areas. A light emission area may emit light when a current is generated from a driving element of a pixel circuit.

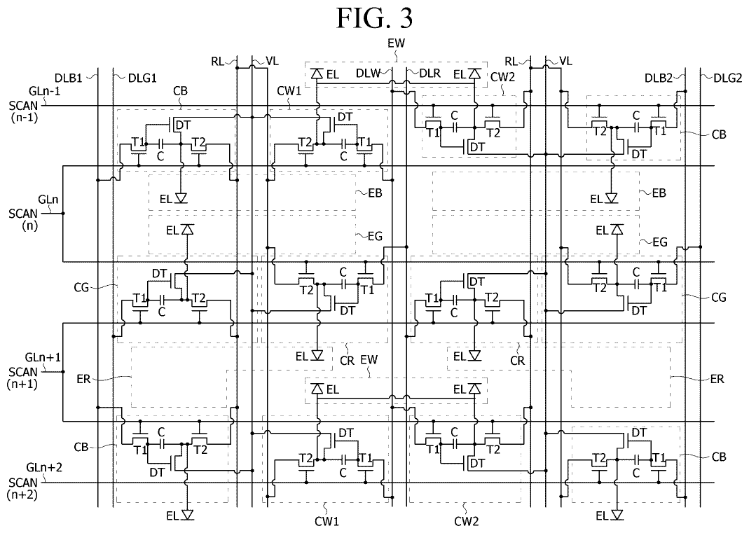

In the white sub-pixel, the fourth light emission area EW may be driven by one or two fourth pixel circuits CW1 and CW2. As shown in FIG. 3, the (4-1)th pixel circuit CW1 and the (4-2)th pixel circuit CW2 may be connected to different gate lines, sequentially receiving gate pulses, and may drive the light-emitting element of the white sub-pixel.

On the first vertical reference line VR1, the first pixel circuit CB of the first pixel PXL1, the left side of the first light emission area EB, the left side of the second light emission area EG, the second pixel circuit CG, and the left side of the third light emission area ER are disposed from top to bottom. On the second vertical reference line VR2, the right side of the first light emission area EB of the first pixel PXL1, the right side of the second light emission area EG, the third pixel circuit CR, the right side of the third light emission area ER, the left side of the fourth light emission area EW, and the (4-1)th pixel circuit CW1 are disposed from top to bottom. On the third vertical reference line VR3, the left side of the first light emission area EB of the second pixel PXL2, the left side of the second light emission area EG, the third pixel circuit CR, the left side of the third light emission area ER, the right side of the fourth light emission area EW, and the (4-2)th pixel circuit CW2 are disposed from top to bottom. On the fourth vertical reference line VR4, the first pixel circuit CB of the second pixel PXL2, the right side of the first light emission area EB, the right side of the second light emission area EG, the second pixel circuit CG, and the right side of the third light emission area ER are disposed from top to bottom.

Light emission areas of the same color may be disposed along the X-axis direction in the first and second pixels PXL1 and PXL2. For example, the first light emission areas EB of the first and second pixels PXL1 and PXL2 are disposed on the virtual first horizontal reference line HR1 parallel to the X-axis direction, and the second light emission areas EG of the first and second pixels PXL1 and PXL2 are disposed on the virtual second horizontal reference line HR2 parallel to the X-axis direction under the first light emission areas EB. Upper portions of the third light emission areas ER of the first and second pixels PXL1 and PXL2 are disposed on the virtual third horizontal reference line HR3 parallel to the X-axis direction under the second light emission areas EG, and lower portions of the third light emission areas ER of the first and second pixels PXL1 and PXL2 and the fourth light emission areas EW are disposed on the virtual fourth horizontal reference line HR4 under the third horizontal reference line HR3. To improve color reproduction rate, a size of the third light emission area ER generating red light may be greater than that of the first and second light emission areas EB and EG.

The fourth light emission area EW generating white light is not continuous on the display panel 100. For this reason, when the entire display area AA of the display panel 100 displays a single color or a specific intermediate grayscale, it is possible to prevent a phenomenon in which a white horizontal line pattern or a vertical line pattern is visually recognized.

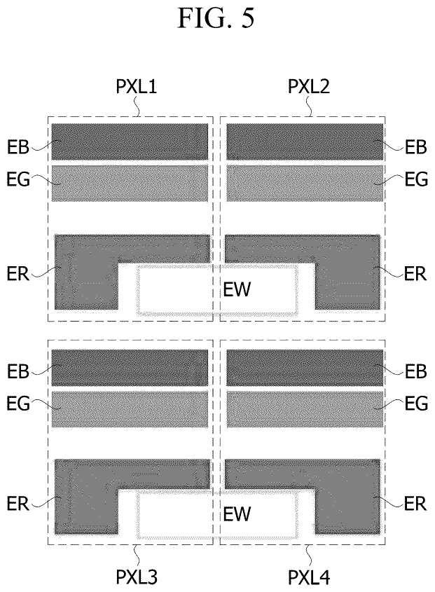

The third light emission area ER may be an L-shaped light emission area with one side removed from the square. The upper portion of the third light emission area ER includes a portion 20 having a narrow width adjacent to the upper end of the fourth light emission area EW. The fourth light emission area EW is disposed in an area secured by removing a portion of a lower portion of each of the third light emission area ER of the first pixel PXL1 and the third light emission area ER of the second pixel PXL2, which are adjacent to each other in a left-right mirror symmetry. The top, left and right sides of the fourth light emission area EW are surrounded by the third light emission areas ER of the first and second pixels PXL1 and PXL2, and the first light emission areas EB of the third and fourth pixels (see FIG. 5) are disposed below the fourth light emission area EW. Accordingly, the fourth light emission area EW is not adjacent to the other fourth light emission area EW.

The power lines PL10 and PL20 may supply constant voltages required for driving the pixels PXL1 and PXL2 to the pixel circuits CB, CG, CR, CW1, and CW2. A pixel driving voltage may be applied to an EVDD power line VL, and a reference voltage may be applied to the REF line RL. The EVDD power line VL is connected to all pixel circuits CB, CG, CR, CW1, and CW2 adjacent to each other in the X-axis direction with the EVDD power line VL interposed therebetween, and supplies the pixel driving voltage to the pixel circuits CB, CG, CR, CW1, and

CW2. The REF line RL may be disposed on both sides with the EVDD power line VL having a relatively larger width interposed therebetween, and may be connected to each other on the non-display area NA. The REF line RL is connected to all pixel circuits CB, CG, CR, CW1, and CW2 adjacent to each other in the X-axis direction with the REF line RL interposed therebetween, and supplies a reference voltage to the pixel circuits CB, CG, CR, CW1, and CW2.

The power lines VL and RL intersect the first light emission area EB, the second light emission area EG, and the third light emission area ER in each of the first and second pixels PXL1 and PXL2, and overlap the light emission areas EB, EG, and ER. The power lines VL and RL avoid the fourth light emission areas EW and do not overlap the fourth light emission area EW.

The first data line pair DL10 includes a first data line DLB1 to which a data voltage of B data is applied and a second data line DLG1 to which a data voltage of G data is applied. The first data line DLB1 is commonly connected to the first pixel circuits CB of pixels adjacent to each other in the X-axis direction with the first data line DLB1 interposed therebetween to supply a data voltage of B data to the first pixel circuits CB. The second data line DLG1 is commonly connected to the second pixel circuits CG of pixels adjacent to each other in the X-axis direction with the second data line DLG1 interposed therebetween to supply a data voltage of G data to the second pixel circuits CG.

The first data line DLB1 is connected to a plurality of first pixel circuits CB disposed along the Y-axis direction. The first data line DLB1 transfers, from the data driver 110, a data voltage of B data to be written in the blue sub-pixels to the first pixel circuits CB. Only a data voltage of B data is applied to the first data line DLB1. The second data line DLG1 is connected to a plurality of second pixel circuits CG disposed along the Y-axis direction. The second data line DLG1 transfers, from the data driver 110, a data voltage of G data to be written in the green sub-pixels to the second pixel circuits CG. Only a data voltage of G data is applied to the second data line DLG1.

The second data line pair DL20 includes a third data line DLR to which a data voltage of R data is applied and a fourth data line DLW to which a data voltage of W data is applied. The third data line DLR is commonly connected to the third pixel circuit CR of pixels PXL1 and PXL2 adjacent to each other in the X-axis direction with the third data line DLR interposed therebetween to supply a data voltage of R data to the third pixel circuits CR. The fourth data line DLW is commonly connected to the fourth pixel circuits CW1 and CW2 of pixels PXL1 and PXL2 adjacent to each other in the X-axis direction with the fourth data line DLW interposed therebetween to supply a data voltage of W data to the fourth pixel circuits CW1 and CW2.

The third data line DLR is connected to a plurality of third pixel circuits CR disposed along the Y-axis direction. The third data line DLR transfers, from the data driver 110, a data voltage of R data to be written in the red sub-pixels to the third pixel circuits CR. Only a data voltage of R data is applied to the third data line DLR. The fourth data line DLW is connected to a plurality of fourth pixel circuits CW1 and CW2 disposed along the Y-axis direction. The fourth data line DLW transfers, from the data driver 110, a data voltage of W data to be written in the white sub-pixels to the fourth pixel circuits CW1 and CW2. Only a data voltage of W data is applied to the fourth data line DLW.

The second data line pair DL20 crosses the fourth light emission area EW and overlaps the fourth light emission area EW. The second data line pair DL20 avoids the elements EB, EG, ER, CB, CG, CR, CW1, and CW2 so as not to overlap the other light emission areas EB, EG, and ER and the pixel circuits CB, CG, CR, CW1, and CW2.

The third data line pair DL30 includes a fifth data line DLB2 to which a data voltage of B data is applied and a sixth data line DLG2 to which a data voltage of G data is applied. The fifth data line DLB2 receives only a data voltage of B data to be supplied to the blue sub-pixels from the data driver 110. The sixth data line DLG2 receives only a data voltage of G data to be supplied to the green sub-pixels from the data driver 110. The fifth data line DLB2 is commonly connected to the first pixel circuits CB of pixels adjacent to each other in the X-axis direction with the fifth data line DLB2 interposed therebetween to supply a data voltage of B data to the first pixel circuits CB. The sixth data line DLG2 is commonly connected to the second pixel circuits CG of pixels adjacent to each other in the X-axis direction with the sixth data line DLG2 interposed therebetween to supply a data voltage of G data to the second pixel circuits CG. The fifth data line DLB2 is connected to a plurality of first pixel circuits CB disposed along the Y-axis direction, and the sixth data line DLG2 is connected to a plurality of second pixel circuits CG disposed along the Y-axis direction.

Each of the gate lines is disposed for each pixel line, and two adjacent gate lines are commonly connected to one output terminal of the gate driver 120. For example, as shown in FIGS. 2 and 3, two gate lines disposed with light emission areas of two different colors interposed therebetween may be connected to each other to be connected to a specific output terminal of the gate driver 120. Therefore, gate pulses SCAN(n−1) to SCAN(n+2) may be simultaneously applied to two pixel lines.

The (n)th gate pulse SCAN(n) (where n is a natural number) may be simultaneously applied to the pixel circuits CB, CG, CR, CW1 and CW2 disposed in two pixel lines through the (n)th gate line GLn. In FIG. 2, some pixel circuits CW2 connected to the (n)th gate line GLn are omitted. The gate pulses SCAN(n−1) to SCAN(n+2) are sequentially applied to the gate lines GLn−1 to GLn+2 in the sequence of the gate lines GLn−1, GLn, GLn+1, and GLn+2.

The light emission area distribution of sub-pixels for each color may be appropriately selected in consideration of color reproduction rate and high luminance. For example, an image or a display model in which high luminance with respect to color reproduction rate is prioritized may increase the area of the fourth light emission area EW, and increase the driving voltages of three sub-pixels excluding the white sub-pixel. The structure of the third and fourth light emission areas ER and EW shown in FIG. 2 is easy to expand or reduce the size of the fourth light emission area EW parallel to the horizontal reference line, and thus, the area distribution of the third and fourth light emission areas ER and EW is easy without changing the shape of wires. In the case of a display model in which pure color is prioritized, the fourth light emission area EW may be reduced. In the case of a display model that require high brightness, the fourth light emission area EW may be increased.

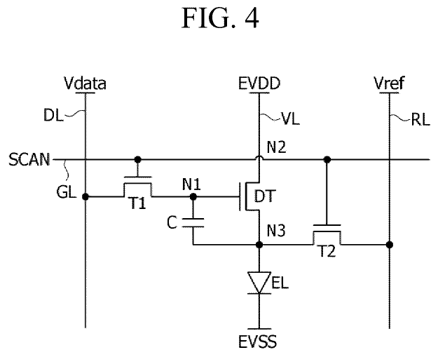

FIG. 3 is an equivalent circuit diagram illustrating in detail one example of the pixel circuits illustrated in FIG. 2. FIG. 4 is an example of a circuit diagram illustrating a single pixel circuit.

Referring to FIGS. 3 and 4, each of the pixel circuits CB, CG, CR, CW1, and CW2 is connected to a respective one of the data lines DL (e.g., DLB1, DLG1, DLW, DLR, DLB2, and DLG2) to which the respective data voltage Vdata of respective pixel data is applied, a respective one of gate lines GL (e.g., GL(n−1) to GL(n+2)) to which a respective one of gate pulses SCAN(n−1) to SCAN(n+2) is applied, a EVDD power line to which a pixel driving voltage EVDD is applied, a VDD power line to which a cathode voltage EVSS is applied, and a REF line to which the reference voltage Vref is applied.

Each of the pixel circuits CB, CG, CR, CW1, and CW2 is connected to a respective light-emitting element EL, and includes a plurality of transistors DT, T1, and T2, and a capacitor C.

The light-emitting element EL may be an organic light emitting diode (OLED) or an inorganic light-emitting element such as a micro LED. The light-emitting element EL may include a red light-emitting element, a green light-emitting element, and a blue light-emitting element, but is not limited thereto. The anode electrode of the light-emitting element EL is electrically connected to a driving element DT or is disposed in a corresponding light emission area in each pixel. When a current from the driving element DT is generated, the light-emitting element EL is driven to emit light, and the light is emitted to the outside of the display panel 100 through the light emission area.

The driving element DT generates a current according to a gate-source voltage to drive the light-emitting element EL. The driving element DT includes a gate electrode connected to a first node N1, a first electrode connected to a second node N2, and a second electrode connected to a third node N3. A capacitor C is connected between the first node N1 and the third node N3. The second node N2 is connected to the EVDD power line VL. The third node N3 is connected to the anode electrode of the light-emitting element EL. The cathode electrode of the light-emitting element EL is connected to a power line to which the cathode voltage EVSS is applied.

The first switch element T1 is connected between the data line DL and the first node N1. The first switch element T1 is turned on in response to the gate pulse SCAN. When the first switch element T1 is turned on, the data voltage Vdata of the pixel data is applied to the first node N1 so that the pixel data is written to the sub-pixel. The first switch element T1 includes a gate electrode connected to the gate line GL, a first electrode connected to the data line DL, and a second electrode connected to the first node N1.

The second switch element T2 is connected between the third node N3 and the REF line RL. The second switch element T2 is turned on in response to the gate pulse SCAN. When the second switch element T2 is turned on, the third node N3 is connected to the REF line RL. The second switch element T2 includes a gate electrode that is connected to the gate line GL, a first electrode that is connected to the third node N3, and a second electrode that is connected to the REF line RL.

The driving element DT must have uniform electrical characteristics in all sub-pixels, but there may be differences between sub-pixels due to process deviation and element characteristic deviation, and the differences may increase as the driving time of the sub-pixels passes. To compensate for the deviation of the electrical characteristics of the driving element DT, an external compensation circuit may be applied to the display panel driving circuit.

The external compensation circuit compensates for the electrical characteristics of the driving element DT by sensing it in real time in the sensing mode. The sensing mode is divided into before and after the product is shipped. The electrical characteristics of the driving element DT in each of the sub-pixels are sensed through the REF line RL, which is connected to the pixels, before the product is shipped, and based on the sensing result, the deviation of the electrical characteristics of the driving element DT for each sub-pixel is compensated.

After shipping the product, the sensing mode may be divided into ON RF mode performed in the power on sequence, RT mode performed in the vertical blank period (VB) during the display driving period, and OFF RS mode performed in the power off sequence.

In the ON RF mode, the external compensation circuit senses the mobility of the driving element DT driving the light-emitting element in each of the sub-pixels through the REF line RL when the display device is powered on, and compares the mobility sensing result with the mobility compensation value of the driving element measured for each sub-pixel before shipping the product to update the mobility compensation value based on the difference. In the sensing mode before shipment of the product, the threshold voltage and mobility of the driving element DT for each sub-pixel are sensed, and the threshold voltage compensation value and mobility compensation value of the driving element are set in a lookup table. The mobility of the driving element is compensated with a mobility compensation value reflecting the mobility sensing result of the driving element for each sub-pixel.

The RT mode senses the mobility of the driving element DT through the REF line RL in real time during the vertical blank period VB for each frame period during the display driving period in which an image is displayed, and updates the mobility compensation value for each sub-pixel according to the mobility sensing result. The vertical blank period is a period in which data is not input to the timing controller 130 between the active interval of the (n−1)th frame period and the active interval of the (n)th frame period.

In the OFF RS mode, when the power of the display device is turned off, the external compensation circuit senses the threshold voltage of the driving element DT in each of the sub-pixels through the REF line RL, and updates the threshold voltage compensation value for each sub-pixel based on the threshold voltage sensing result. In the OFF RS mode, the display panel driving circuit and the external compensation circuit are driven for a preset delay time before the power is completely turned off to sense the threshold voltage of the driving element DT in each of the sub-pixels to update the threshold voltage compensation value of the driving element DT for each sub-pixel.

The external compensation circuit includes an analog to digital converter (hereinafter referred to as “ADC”) electrically connected to the REF line RL, and a compensation circuit that receives data output from the ADC. In the lookup table of the compensation circuit, compensation values for compensating threshold voltages and mobility of driving elements driving the light-emitting elements for each sub-pixel are stored. The compensation circuit compensates for changes in electrical characteristics of the driving element by inputting the sensing data output from the ADC into the lookup table, and adding or multiplying the compensation value output from the lookup table to the pixel data of the input image to modulate the pixel data. The ADC may be disposed on each sensing channel set in the source drive IC in which the data driver 110 is integrated. The compensation circuit may be implemented as a logic circuit of the timing controller 130.

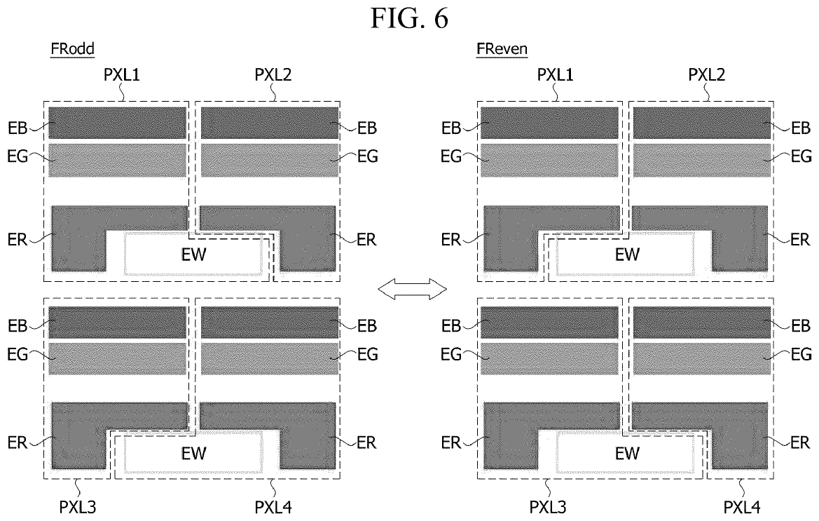

FIG. 5 is an example of a diagram illustrating light emission areas of 2×2 pixels. FIGS. 6 to 9 are diagrams illustrating one example of a hybrid driving method.

Referring to FIGS. 5 to 9, the third and fourth pixels PXL3 and PXL4 having substantially the same structure as the first and second pixels PXL1 and PXL2 may be disposed under (or below) the first and second pixels PXL1 and PXL2.

The first to fourth pixels PXL1 to PXL4 may be driven in a hybrid way, as illustrated in FIGS. 6 to 9. In a predetermined unit of time, the first to fourth pixels PXL1 to PXL4 may be alternately driven with four sub-pixels and three sub-pixels. For example, during the odd-numbered frame period Fodd, as illustrated in FIG. 6, the first and fourth pixels PXL1 and PXL4 may be driven with four sub-pixels, and the second and third pixels PXL2 and PXL3 may be driven with three sub-pixels. During the even-numbered frame period Feven, as illustrated in FIG. 6, the first and fourth pixels PXL1 and PXL4 may be driven with three sub-pixels, and the second and third pixels PXL2 and PXL3 may be driven with four sub-pixels. When the first pixel PXL1 is driven with four sub-pixels, W data written to the white sub-pixel is generated from R, G, and B data of the first pixel PXL1. When the second pixel PXL2 is driven with four sub-pixels, W data written to the white sub-pixel is generated from R, G, and B data of the second pixel PXL2. When the third pixel PXL3 is driven with four sub-pixels, W data written to the white sub-pixel is generated from R, G, and B data of the third pixel PXL3. When the fourth pixel PXL4 is driven with four sub-pixels, W data written to the white sub-pixel is generated from R, G, and B data of the fourth pixel PXL4.

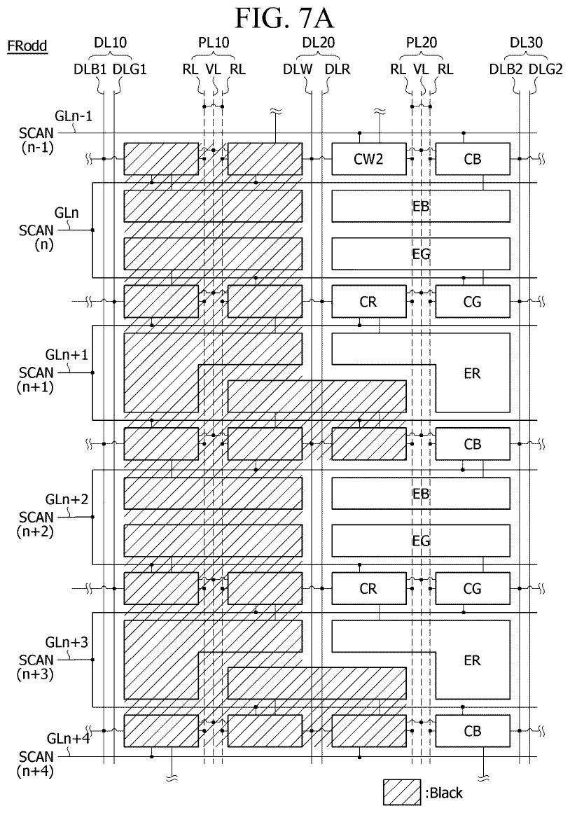

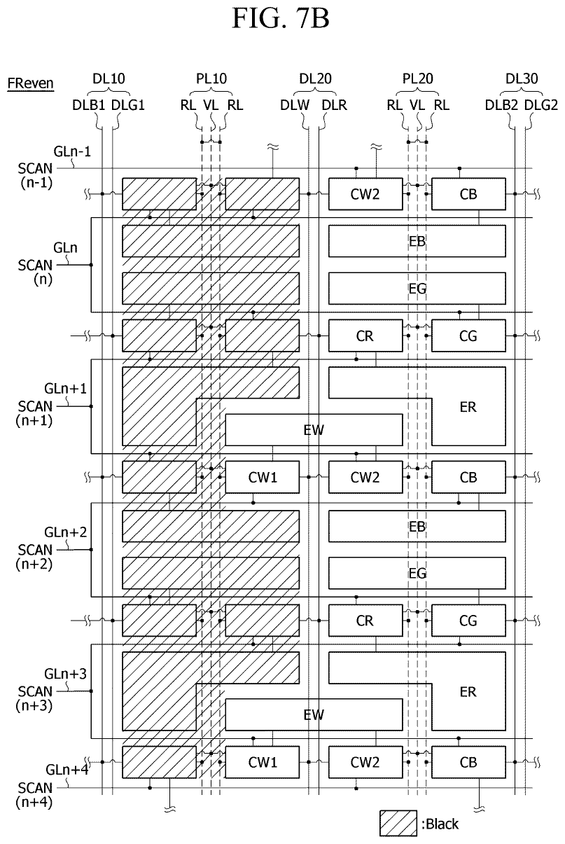

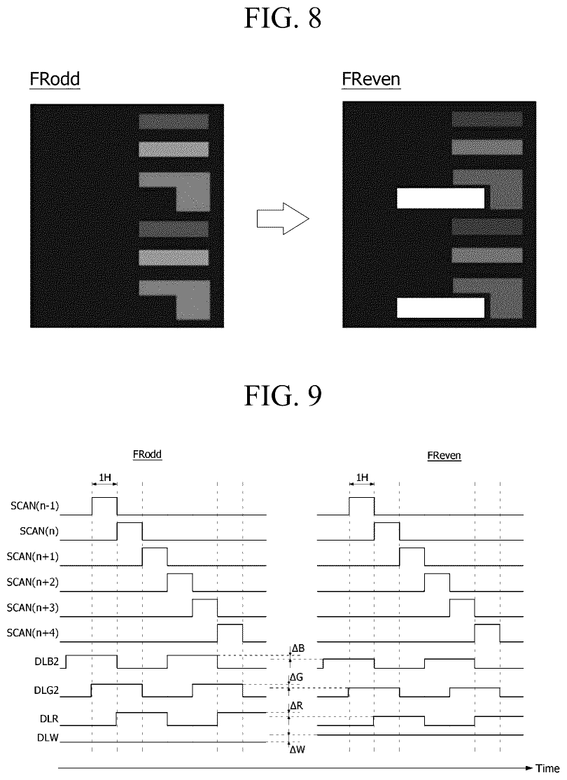

FIGS. 7A to 8 show another example in which the first to fourth pixels PXL1 to PXL4 are driven in a hybrid way when the first and third pixels PXL1 and PXL3 on the left side display black in 2×2 pixels and the second and fourth pixels PXL2 and PXL4 on the right side display the intermediate grayscales. FIG. 9 is a diagram illustrating a gate pulse and a data voltage in the hybrid driving method illustrated in FIGS. 7A to 8. In FIGS. 9, B and G data voltages of a black grayscale are omitted. The differences ΔB, ΔG, ΔR, and ΔW between the data voltages of the intermediate grayscale in the odd-numbered frame period Fodd and the even-numbered frame period Feven indicate data voltage differences generated according to the presence or absence of W data when the second and fourth pixels are driven with three sub-pixels and four sub-pixels.

Referring to FIGS. 7A, 8, and 9, during the odd-numbered frame period Fodd, the first and third pixels PXL1 and PXL3 may be driven with four sub-pixels to display black, and the second and fourth pixels PXL2 and PXL4 may be driven with three sub-pixels to display intermediate grayscale. In this case, since the second and fourth pixels PXL2 and PXL4 are driven with three sub-pixels, the data voltage of W data is a black grayscale voltage.

Referring to FIGS. 7B, 8 and 9, during the even-numbered frame period Feven, the first and third pixels PXL1 and PXL3 may be driven with three sub-pixels to display black, and the second and fourth pixels PXL2 and PXL4 may be driven with four sub-pixels to display intermediate grayscales. In this case, the W data written to the white sub-pixels of the second and fourth pixels PXL2 and PXL4 may be generated with a minimum grayscale value in the R, G, and B data, so that the data voltage thereof may be higher than the black grayscale value, while the data voltages of the R, G, and B data may be lowered.

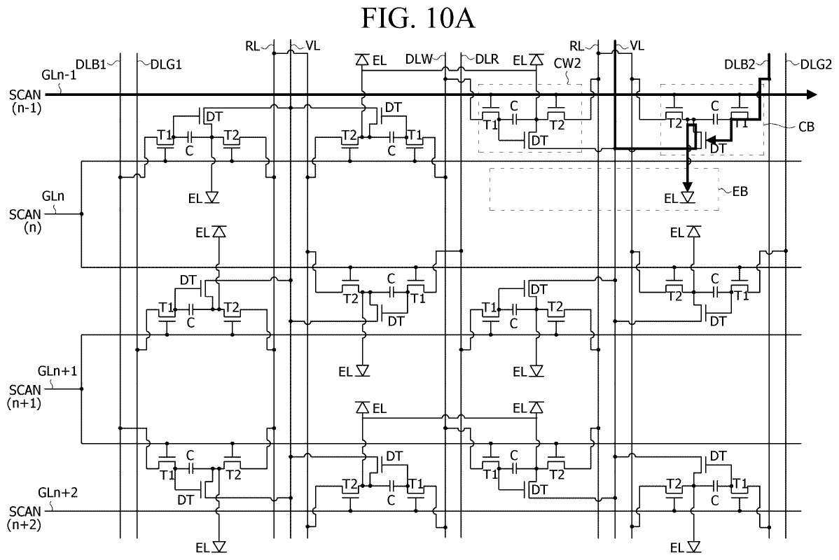

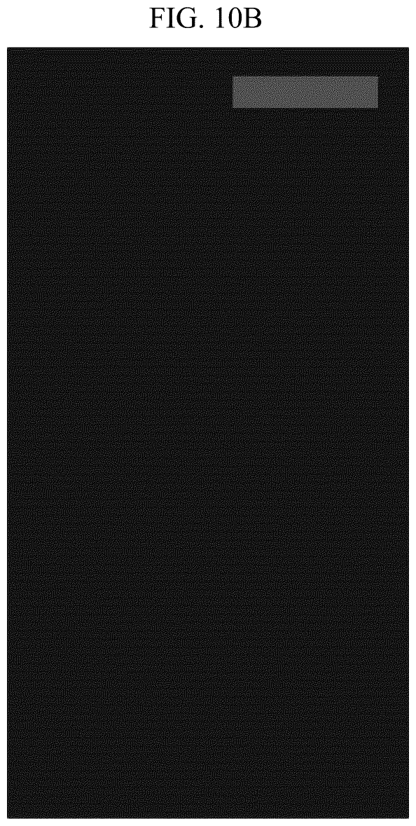

FIGS. 10A to 13B are examples of diagrams sequentially illustrating a driving sequence of pixels shown in FIG. 2 in units of one horizontal period. In FIGS. 10A to 13B, two light-emitting elements EL are illustrated as being connected to the pixel circuit, but one light-emitting element EL may be connected to the pixel circuit.

Referring to FIGS. 10A and 10B, the (n−1)th gate pulse SCAN(n−1) is applied to the (n−1)th gate line GLn−1 during the (n−1)th horizontal period (where n is a natural number). In this case, the first pixel circuit CB of the second pixel PXL2 connected to the (n−1)th gate line GLn−1 may be driven so that the first light emission area EB of the second pixel PXL2 may emit light.

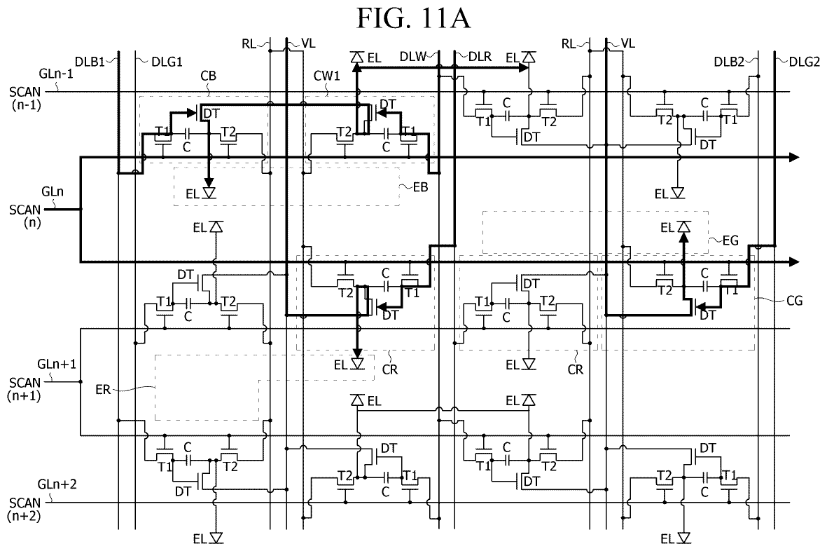

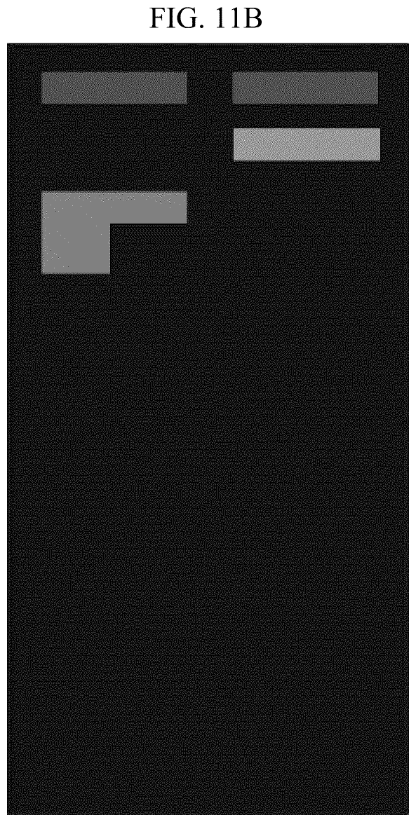

Referring to FIGS. 11A and 11B, the (n)th gate pulse SCAN(n) is applied to the (n)th gate line GLn during the (n)th horizontal period. In this case, the first and third pixel circuits CB and CR of the first pixel PXL1 and the second pixel circuit CG of the second pixel PXL2 connected to the (n)th gate line GLn may be driven to emit light from the first and third light emission areas EB and ER of the first pixel PXL1 and the second light emission area EG of the second pixel PXL2.

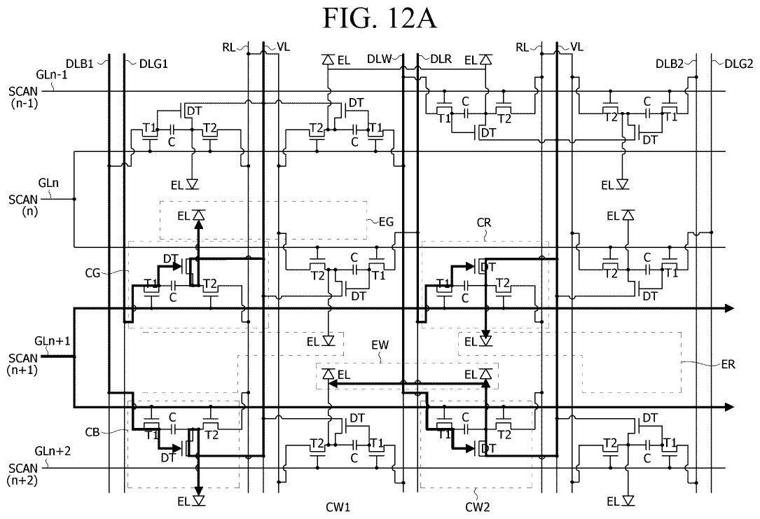

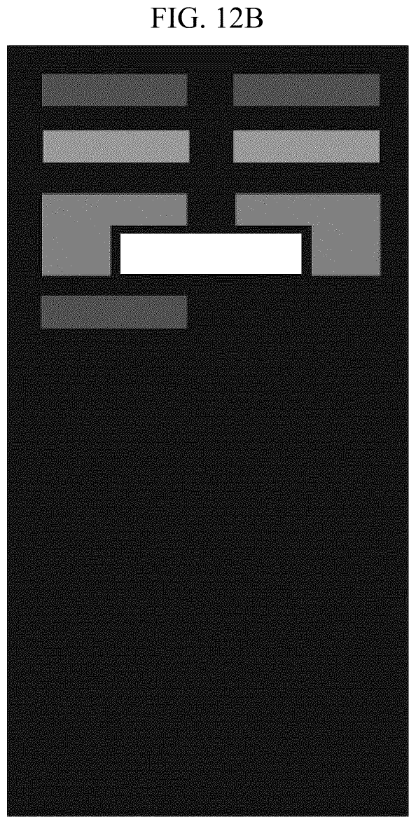

Referring to FIGS. 12A and 12B, the (n+1)th gate pulse SCAN(n+1) is applied to the (n+1)th gate line GLn+1 during the (n+1)th horizontal period. In this case, the second pixel circuit CG of the first pixel PXL1, the first pixel circuit CB of the third pixel PXL3, the third pixel circuit CR of the second pixel PXL2, and the (4-2)th pixel circuit CW2 connected to the (n+1)th gate line GLn+1 may be driven so that the second light emission area EG of the first pixel PXL1, the first light emission area EB of the third pixel PXL3, the third light emission area ER of the second pixel PXL2, and the forth light emission area EW may emit light. In FIG. 12A, the third pixel PXL3 is omitted.

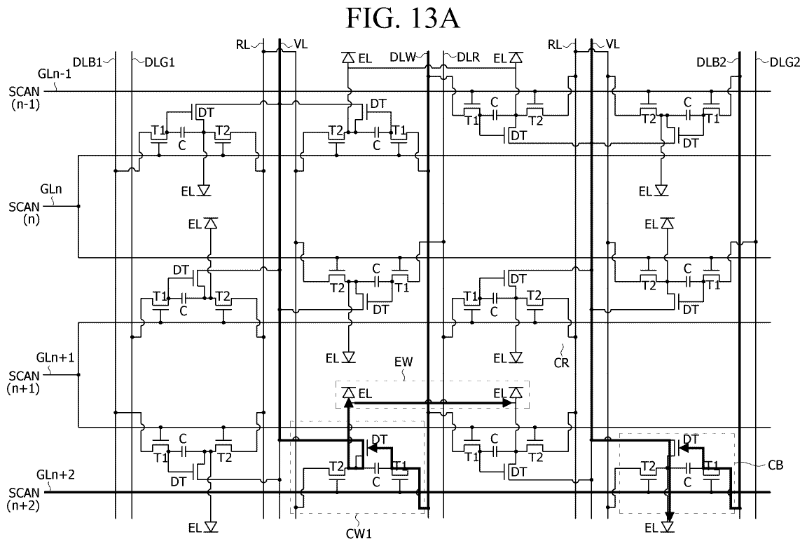

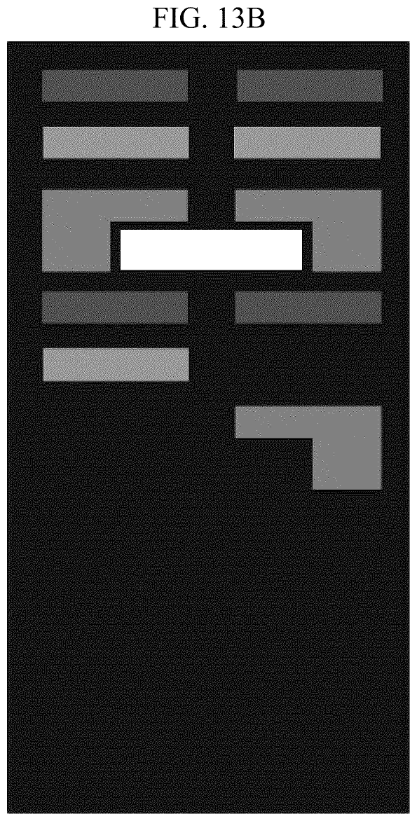

Referring to FIGS. 13A and 13B, the (n+2)th gate pulse SCAN(n+2) is applied to the (n+2)th gate line GLn+2 during the (n+2)th horizontal period. In this case, the second pixel circuit CG of the third pixel PXL3, the first and third pixel circuits CB and CR of the fourth pixel PXL4, and the (4-1)th pixel circuit CW1 connected to the (n+2)th gate line GLn+2 may be driven to emit light from the second light emission area EG of the third pixel PXL3, the first and third light emission areas EB and ER of the fourth pixel PXL4, and the fourth light emission area EW. In FIG. 13A, the third and fourth pixels PXL3 and PXL4 is omitted.

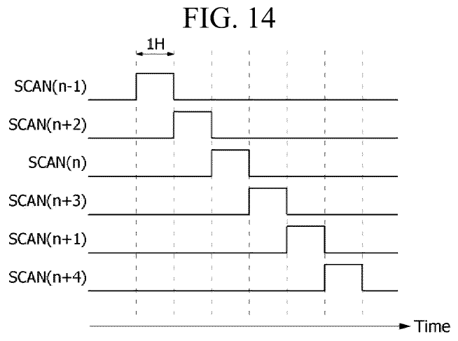

FIG. 14 is a waveform diagram illustrating one example in which gate pulses are alternated.

Referring to FIGS. 7A, 7B, and 14, the gate driver 120 may output gate pulses to the gate lines GLn−1 to GLn+4 in an alternating order such as SCAN(n−1), SCAN(n+2), SCAN(n), SCAN(n+3), SCAN(n+1), and SCAN(n+4). In this case, since the data voltages of the same color are applied to the data lines during the two horizontal periods, the amount of toggling, the number of transitions, the amplitude of transitions, etc. of the data voltage may be reduced, and a slew rate of the data voltage may be improved. For example, the (n−1)th gate pulse SCAN(n−1) output during the (n−1)th horizontal period is synchronized with the data voltage of B data. Subsequently, the (n+2)th gate pulse SCAN(n+2) output during the (n+2)th horizontal period is synchronized with the data voltage of the next B data. In this case, since the data voltages of the same color may be continuously applied during the 2 horizontal periods, the amount of toggling, the number of transitions, the amplitude of transitions, etc. of the data voltage may be reduced, and the slew rate of the data voltage may be improved. Generally, data voltages of the same color in neighboring pixels are similar grayscale voltages.

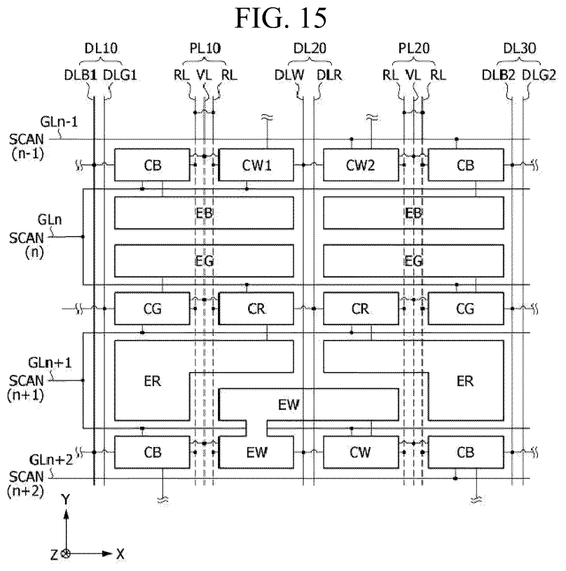

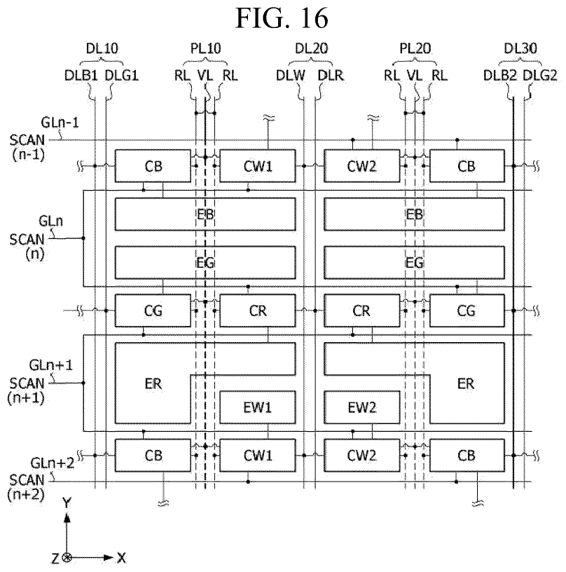

FIGS. 15 and 16 are diagrams illustrating pixel configurations according to other example embodiments of the present disclosure. In FIGS. 15 and 16, redundant descriptions for configurations substantially identical to those of the above-described embodiments will be omitted.

Referring to FIG. 15, the white sub-pixel may include a single pixel circuit CW and a fourth light emission area EW connected to the single pixel circuit CW to emit white light, as shown in FIG. 15. When the anode electrode of the fourth light emission area EW is connected to the single pixel circuit CW, the pixel circuit area is reduced, and thus the fourth light emission area EW is increased, thereby further improving the aperture ratio.

Referring to FIG. 16, a white sub-pixel may include two independently driven light emission areas. The fourth light emission area EW may be divided into the (4-1)th light emission area EW1 and the (4-2)th light emission area EW2. The (4-1)th light emission area EW1 and the (4-2)th light emission area EW2 are electrically separated from each other and are independently driven by different pixel circuits CW1 and CW2. The (4-1)th light emission area EW1 is driven by the (4-1)th pixel circuit CW1, and the (4-2)th light emission area EW2 is driven by the (4-2)th pixel circuit CW2.

The (4-1)th light emission area EW1 and the (4-2)th light emission area EW2 may be separated from each other with the data lines DLW and DLR interposed therebetween, and may not overlap the data lines DLW and DLR as illustrated in FIG. 16.

Since the (4-1)th light emission area EW1 and the (4-2)th light emission area EW2 are driven by different pixel circuits CW1 and CW2, they may be driven with different brightnesses. The white sub-pixel may express the luminance of pixels in detail by expressing the luminance of decimal grayscale values. The timing controller 130 may generate first W data written to the (4-1)th pixel circuit CW1 and second W data written to the (4-2)th pixel circuit CW2 from R, G, and B data of pixels driven with four sub-pixels. The first W data and the second W data may be generated with the same grayscale value or different grayscale value.

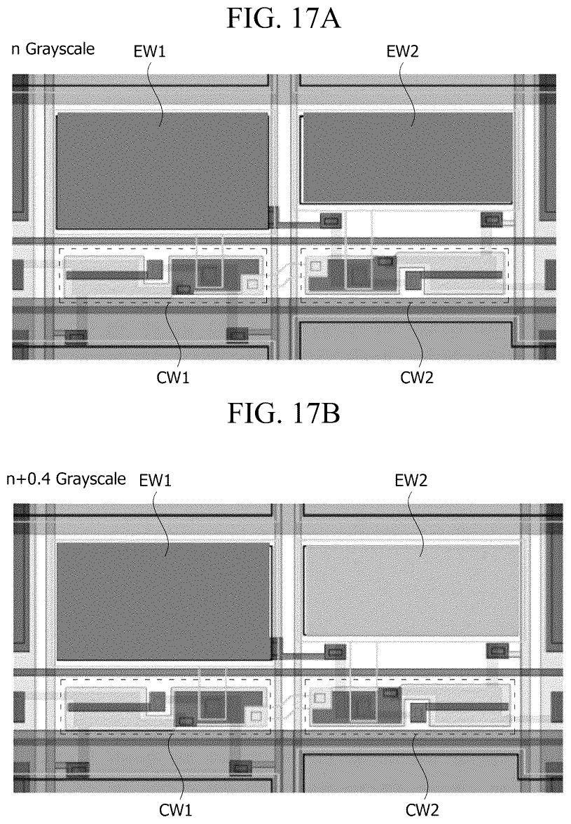

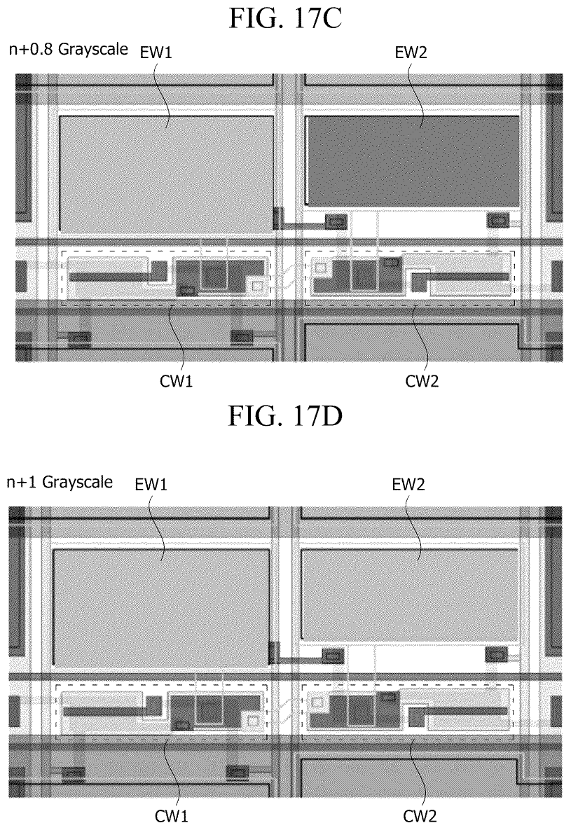

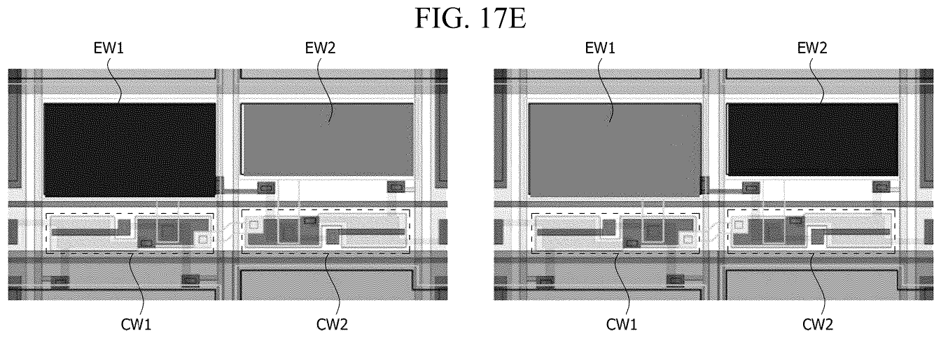

The luminance in the light emission area of one white sub-pixel may be partially differently controlled by writing different W data in the (4-1)th pixel circuit CW1 and the (4-2)th pixel circuit CW2. As a result, the luminance of the white sub-pixel may be controlled to be the luminance of the decimal grayscale value. For example, as shown in FIG. 17A, the (4-1)th and (4-2)th light emission areas EW1 and EW2 of the white sub-pixel may be emitted with the luminance of the same n grayscale (where n is a natural number). The (4-1)th and (4-2)th light emission areas EW1 and EW2 of the white sub-pixel may be emitted with the luminance of different grayscale values, and thus may be emitted with the luminance of n+0.4 grayscale or n+0.8 grayscale, as shown in FIGS. 17B and 17C. The (4-1)th and (4-2)th light emission areas EW1 and EW2 of the white sub-pixel may be emitted with the luminance of different grayscale values, and may be emitted with the luminance of n+1 grayscale, as shown in FIG. 17D. The (4-1)th and (4-2)th light emission areas EW1 and EW2 of the white sub-pixel may be emitted with the luminance of different grayscale values, and may be emitted with the luminance of n or less decimal grayscale values, as shown in FIG. 17E.

In an example, a fourth-1 pixel circuit may denote a (4-1)th pixel circuit, and a fourth-2 pixel circuit may denote a (4-2)th pixel circuit. In an example, a fourth-1 light emission area may denote a (4-1)th light emission area, and a fourth-2 light emission area may denote a (4-2)th light emission area.

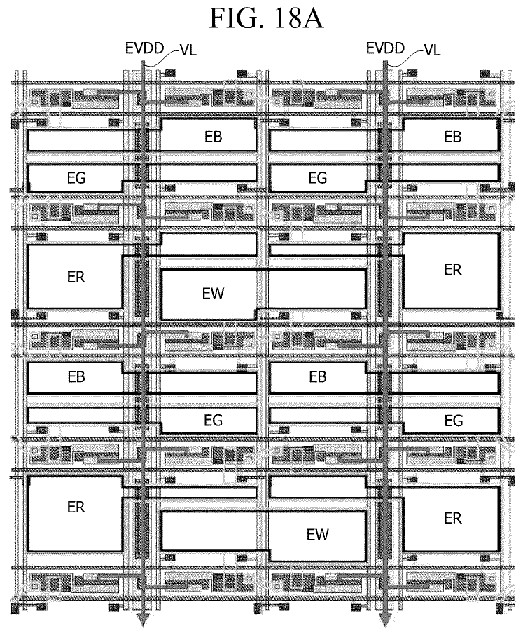

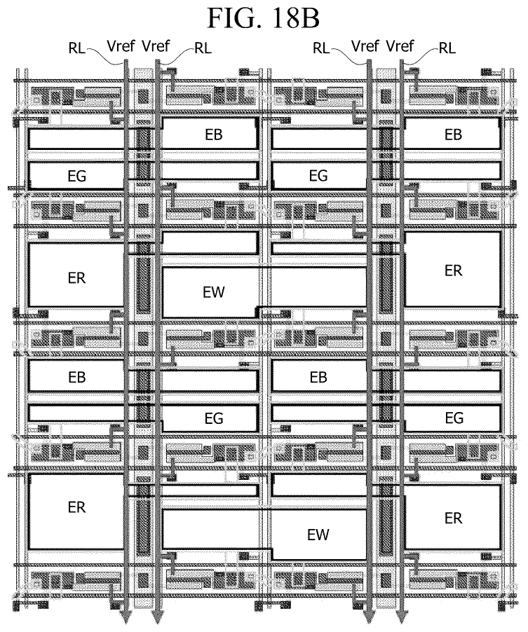

FIGS. 18A and 18B are examples of diagrams illustrating paths in which a constant voltage required for pixel driving is applied to pixels.

Referring to FIGS. 18A and 18B, the pixel driving voltage EVDD is applied to left and right pixels adjacent to each other on the X-axis direction through the EVDD power line VL in all pixel lines. The reference voltage Vref is applied to left and right pixels adjacent to each other on the X-axis direction through the REF line RL in all pixel lines.

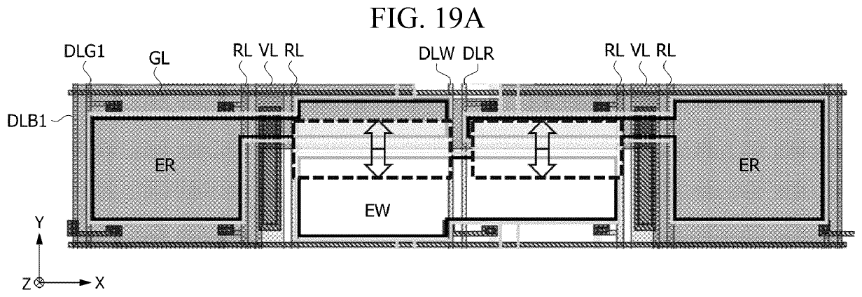

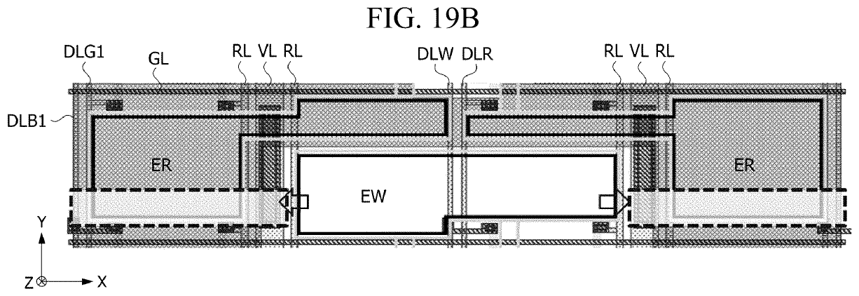

FIGS. 19A and 19B are diagrams illustrating an example in which the size of a light emission area changes without changing the wire of a display panel.

In the pixel structure of a display panel according to an example embodiment of the present disclosure, it is easy to design an area distribution of the third and fourth light emission areas ER and EW without lowering an aperture ratio and changing a structure of the wires. The wires include a data line, a gate line, and a power line on the display panel 100. As illustrated in FIG. 19A, the fourth light emission area EW may be extended in the Y-axis direction, and the width of a small width portion of the upper end in the third light emission area ER may be reduced. As illustrated in FIG. 19B, the fourth light emission area EW may be extended in the X-axis direction, and the width of the third light emission area ER in the Y-axis direction may be reduced.

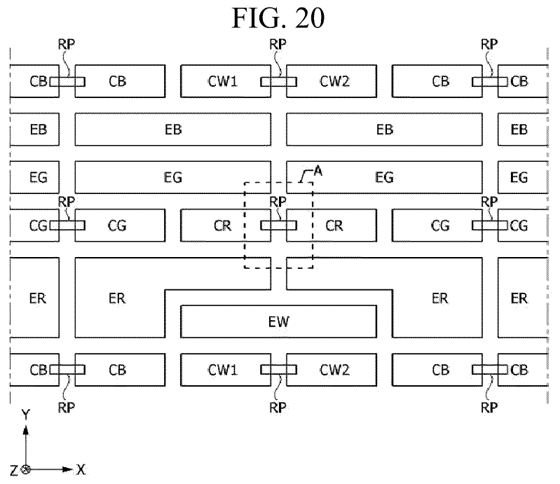

In the pixel structure of the display panel according to an example embodiment of the present disclosure, it is easy to design a repair for defective pixels. This is because pixel circuits for driving sub-pixels of the same color are adjacent in the X-axis direction and the gaps between them are small. If an anode electrode in the light emission area exists on the shortest path between pixel circuits for driving sub-pixels of the same color, the repair pattern is placed to avoid the pattern of the anode electrode, which may reduce the aperture ratio of the pixel. In contrast, in the case of the pixel structure according to an example embodiment of the present disclosure, since there is no light emission area between pixel circuits for driving sub-pixels of the same color as shown in FIG. 20, and the shortest path therebetween is small, a repair pattern may be disposed without a decrease in aperture ratio.

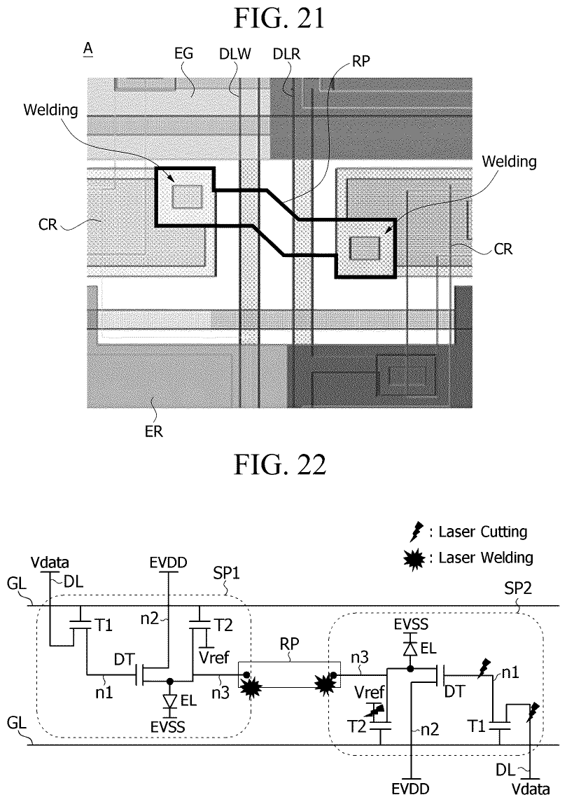

FIG. 20 is a diagram illustrating one example of a repair pattern according to one example embodiment of the present disclosure. FIG. 21 is an example of an enlarged view showing part A shown in FIG. 20 in detail.

Referring to FIGS. 20 and 21, a repair pattern RP may be disposed on the display panel 100 to overlap adjacent pixel circuits in sub-pixels of the same color. The repair pattern RP may be a metal pattern.

A repair pattern RP may be disposed between the first pixel circuits CB-CB adjacent to each other in the X-axis direction. A repair pattern RP may be disposed between the second pixel circuits CG-CG adjacent to each other in the X-axis direction. A repair pattern RP may be disposed between the third pixel circuits CR-CR adjacent to each other in the X-axis direction. A repair pattern RP may be disposed between the (4-1)th pixel circuit CW1 and the (4-2)th pixel circuit CW2 adjacent to each other in the X-axis direction.

When all neighboring sub-pixels overlapping the repair pattern RP are normally driven, the repair pattern RP is not electrically connected to the pixel circuits. In contrast, when any one of the neighboring sub-pixels is detected as a defective sub-pixel, the normal sub-pixel that is normally driven and the defective sub-pixel may be electrically connected to each other through the repair pattern RP in the repair process.

FIG. 22 is a circuit diagram showing one example of a part(s) to be cut and a part(s) to be welded in a repair process.

Referring to FIG. 22, in the repair process, the path between the first switch element T1 and the data line DL is disconnected by laser cutting so that the data voltage Vdata and the reference voltage Vref are not applied to the defective sub-pixel SP2, and the path between the second switch element T2 and the REF line is disconnected by laser cutting. In addition, in the repair process, the first node N1 between the second electrode of the first switch element T1 and the gate electrode of the driving element DT may be disconnected by laser cutting.

In the repair process, the anode electrode of the normal sub-pixel SP1 is connected to the anode electrode of the defective sub-pixel SP2 through the repair pattern RP in order to drive the light-emitting element EL of the defective sub-pixel that is laser-cut using the pixel circuit of the normal sub-pixel SP1. To this end, in the repair process, laser welding may be applied to one end of the repair pattern RP overlapping the third node n3 of the normal sub-pixel SP1, and laser welding may be applied to the other end of the repair pattern RP overlapping the third node n3 of the defective sub-pixel SP2. As a result of the repair process, the pixel circuit of the defective sub-pixel SP2 is electrically separated from the light-emitting element EL, and the anode electrode of the normal sub-pixel SP1 is electrically connected to the anode electrode of the defective sub-pixel SP2 through the repair pattern RP so that the light-emitting element EL of the normal sub-pixel SP1 and the light-emitting element EL of the defective sub-pixel SP2 may be driven by the pixel circuit of the normal sub-pixel SP1. The repair pattern RP allows current generated from the pixel circuit of the normal sub-pixel to be transmitted to the anode electrode of the defective sub-pixel so that the defective sub-pixel may emit light.

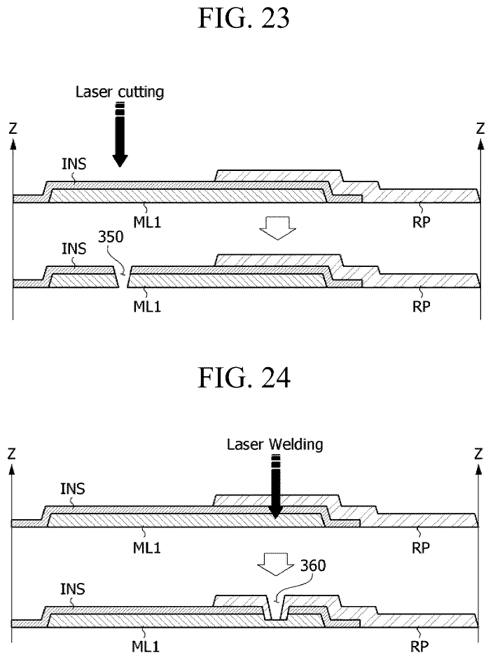

FIGS. 23 and 24 are examples of cross-sectional views schematically showing a laser cutting method and a laser welding method in a repair process.

Referring to FIG. 23, the laser repair equipment irradiates a laser beam to the cutting position 350 of the defective sub-pixel SP2. At the cutting position 350, the conductor pattern ML1 and the repair pattern RP do not overlap. The insulating layer INS and the conductor pattern ML1 may be melted and opened at the cutting position 350 by the energy of the laser beam. In an example, the conductor pattern ML1 of FIG. 23 (or a portion thereof or the cutting position 350) may represent or correspond to a portion of a node (e.g., n1) of the sub-pixel SP2 of FIG. 22 where laser-cutting is applied. In this example, the structure of the layers shown in FIG. 22 is depicted differently from the actual scale and size.

Referring to FIG. 24, the laser repair equipment irradiates a laser beam to a welding position 360 overlapping the repair pattern RP. At the welding position, the conductor pattern ML1 and the repair pattern RP overlap each other with an insulating layer INS interposed therebetween. The insulating layer INS, the conductor pattern ML1 and the repair pattern RP are melted at the welding position 360 by the energy of the laser beam. In this case, the conductor pattern ML1 and the repair pattern RP overlapping at the welding position may be connected to each other. In an example, the conductor pattern ML1 of FIG. 24 (or a portion thereof or the welding position 360) may represent or correspond to a portion of the third node n3 of the sub-pixel SP1 or SP2 shown in FIG. 22.

In FIGS. 23 and 24, the conductor pattern ML1 may be a metal or metalized semiconductor layer. Meanwhile, in the case of an oxide semiconductor such as indium gallium zinc oxide (IGZO), conduction characteristics vary according to an oxygen content. When the oxygen content decreases, the conductivity of the oxide semiconductor increases and be metalized. Plasma treatment may be used as a method of reducing the oxygen content of the oxide semiconductor. For example, when the oxide semiconductor is exposed to plasma (metalizing process), oxygen contained in the oxide semiconductor may be removed and resistance of the oxide semiconductor may decrease, thereby being metalized. Plasma treatment is a method of creating plasma discharge in helium (He), hydrogen (H2), or argon (Ar) gas.

The objects to be achieved by the present disclosure, the means for achieving the objects, and effects of the present disclosure described above do not specify essential features of the claims, and thus, the scope of the claims is not limited to the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The scope of protection of the present disclosure should be construed based on the following claims, and all technical features within the scope of equivalents thereof should be construed as being included within the scope of the present disclosure.

What is claimed is:

1. A display panel, comprising:
a first pixel and a second pixel adjacent to each other in a first direction, wherein:
each of the first pixel and the second pixel includes a first sub-pixel, a second sub-pixel, and a third sub-pixel configured to emit light having different colors;
the first pixel and the second pixel share a white sub-pixel;
each of the first sub-pixels includes a first pixel circuit and a first light emission area connected to the first pixel circuit;
each of the second sub-pixels includes a second pixel circuit and a second light emission area connected to the second pixel circuit;
each of the third sub-pixels includes a third pixel circuit and a third light emission area connected to the third pixel circuit;
the white sub-pixel includes a fourth pixel circuit and a fourth light emission area connected to the fourth pixel circuit; and
the white sub-pixel is disposed between the third sub-pixel of the first pixel and the third sub-pixel of the second pixel in the first direction.

2. The display panel of claim 1, wherein:
the first, second and third light emission areas of the first pixel and the first, second and third light emission areas of the second pixel are respectively arranged in mirror symmetry, and the third light emission areas of the first pixel and the second pixel surround top, left, and right sides of the fourth light emission area; and
first light emission areas of third and fourth pixels positioned below the first and second pixels are disposed below the fourth light emission area.

3. The display panel of claim 1, further comprising:
power lines configured to supply one or more constant voltages to the first, second, third and fourth pixel circuits,
wherein the power lines are disposed along a second direction crossing the first direction to overlap the first light emission area, the second light emission area, and the third light emission area.

4. The display panel of claim 3, wherein the power lines include:
a first power line to which a pixel driving voltage is for being applied; and
second power lines disposed on both sides of the first power line and connected to each other,
wherein a width of the first power line is greater than a width of each of the second power lines.

5. The display panel of claim 3, further comprising:
a plurality of data line pairs configured to supply data voltages of pixel data to the first, second, third and fourth pixel circuits,
wherein the plurality of data line pairs include a first data line pair and a second data line pair,
wherein the first data line pair includes:
a first data line connected to a plurality of first pixel circuits arranged along the second direction; and
a second data line connected to a plurality of second pixel circuits arranged along the second direction,
wherein the second data line pair includes:
a third data line connected to a plurality of third pixel circuits arranged along the second direction; and
a fourth data line connected to a plurality of fourth pixel circuits arranged along the second direction.

6. The display panel of claim 5, wherein the second data line pair overlaps the fourth light emission area.

7. The display panel of claim 1, further comprising:
a plurality of gate lines disposed along the first direction,
wherein:
two light emission areas, among the first, second and third light emission areas and the fourth light emission area of the first and second pixels, are configured to emit light having different colors;
the two light emission areas are disposed between two gate lines among the plurality of gate lines; and
the two gate lines are connected to each other.

8. The display panel of claim 7, wherein the fourth pixel circuit includes:
a fourth-1 pixel circuit connected to the fourth light emission area; and
a fourth-2 pixel circuit connected to the fourth light emission area.

9. The display panel of claim 8, wherein the fourth-1 pixel circuit and the fourth-2 pixel circuit are connected to different gate lines to sequentially receive gate pulses.

10. The display panel of claim 8, wherein the fourth light emission area includes:
a fourth-1 light emission area connected to the fourth-1 pixel circuit; and
a fourth-2 light emission area separated from the fourth-1 light emission area and connected to the fourth-2 pixel circuit.

11. The display panel of claim 1, comprising:
a plurality of sub-pixels;
a plurality of pixel circuits; and
a repair pattern,
wherein:
the plurality of sub-pixels comprise the first, second and third sub-pixels of the first and second pixels and the white sub-pixel;
the plurality of pixel circuits comprise the first, second and third pixel circuits of the first and second pixels and the fourth pixel circuit;
adjacent pixel circuits of a same color are pixel circuits among the plurality of pixel circuits, wherein the pixel circuits are configured to emit light having the same color and are disposed adjacent to each other in the first direction;
the adjacent pixel circuits of the same color are disposed between adjacent sub-pixels among the plurality of sub-pixels or are disposed within a sub-pixel among the plurality of sub-pixels;
the repair pattern overlaps the adjacent pixel circuits of the same color;
an insulating layer is interposed between the repair pattern and the adjacent pixel circuits of the same color; and
the repair pattern is for being selectively electrically connected to the adjacent pixel circuits of the same color.

12. The display panel of claim 1, wherein:
the first sub-pixel is a blue sub-pixel;
the second sub-pixel is a green sub-pixel; and
the third sub-pixel is a red sub-pixel.

13. A display device, comprising:
a display panel in which a plurality of data lines, a plurality of gate lines, a plurality of power lines, and a plurality of pixels are arranged;
a data driver configured to convert pixel data into data voltages and to supply the data voltages to the plurality of data lines;
a gate driver configured to sequentially supply gate pulses to the plurality of gate lines; and
a timing controller configured to transmit the pixel data to the data driver and to control the data driver and the gate driver,
wherein the display panel includes:
a first pixel and a second pixel adjacent to each other in a first direction, and
wherein:
each of the first pixel and the second pixel includes a first sub-pixel, a second sub-pixel, and a third sub-pixel configured to emit light having different colors;
the first pixel and the second pixel share a white sub-pixel;
each of the first sub-pixels includes a first pixel circuit and a first light emission area connected to the first pixel circuit;
each of the second sub-pixels includes a second pixel circuit and a second light emission area connected to the second pixel circuit;
each of the third sub-pixels includes a third pixel circuit and a third light emission area connected to the third pixel circuit;
the white sub-pixel includes a fourth pixel circuit and a fourth light emission area connected to the fourth pixel circuit; and
the white sub-pixel is disposed between the third sub-pixel of the first pixel and the third sub-pixel of the second pixel in the first direction.

14. The display device of claim 13, wherein:
in a first mode, the display device is configured to drive the first pixel with four sub-pixels including the first sub-pixel of the first pixel, the second sub-pixel of the first pixel, the third sub-pixel of the first pixel, and the white sub-pixel, and drive the second pixel with three sub-pixels including the first sub-pixel of the second pixel, the second sub-pixel of the second pixel, and the third sub-pixel of the second pixel; and
in a second mode, the display device is configured to drive the second pixel with four sub-pixels including the first sub-pixel of the second pixel, the second sub-pixel of the second pixel, the third sub-pixel of the second pixel, and the white sub-pixel, and drive the first pixel with three sub-pixels including the first sub-pixel of the first pixel, the second sub-pixel of the first pixel, and the third sub-pixel of the first pixel.

15. The display device of claim 14, wherein:
during an odd-numbered frame period, the display device is configured to drive the first pixel with the four sub-pixels of the first pixel and to drive, at a same time, the second pixel with the three sub-pixels of the second pixel; and
during an even-numbered frame period, the display device is configured to drive the second pixel with the four sub-pixels of the second pixel and to drive, at a same time, the first pixel with the three sub-pixels of the first pixel.

16. The display device of claim 14, wherein the fourth pixel circuit includes:
a fourth-1 pixel circuit connected to the fourth light emission area; and
a fourth-2 pixel circuit connected to the fourth light emission area.

17. The display device of claim 16, wherein the fourth-1 pixel circuit and the fourth-2 pixel circuit are connected to different gate lines and are configured to sequentially receive gate pulses.

18. The display device of claim 16, wherein the fourth light emission area includes:
a fourth-1 light emission area connected to the fourth-1 pixel circuit; and
a fourth-2 light emission area separated from the fourth-1 light emission area and connected to the fourth-2 pixel circuit.

19. The display device of claim 16, wherein:
the fourth light emission area includes a fourth-1 light emission area and a fourth-2 light emission area; and
in a mode, the fourth light emission area is configured to emit light with a luminance of a decimal grayscale value, to provide luminances of the fourth-1 and fourth-2 light emission areas that are different from each other.

20. The display device of claim 13, wherein:
the display device is configured to simultaneously drive the first and second pixels with a set of sub-pixels, in response to an input image being a pure color or a saturation of the input image being greater than or equal to a preset reference value; and
the set of sub-pixels includes the first sub-pixel of the first pixel, the second sub-pixel of the first pixel, the third sub-pixel of the first pixel, the first sub-pixel of the second pixel, the second sub-pixel of the second pixel, and the third sub-pixel of the second pixel.

21. The display device of claim 13, wherein:
the third light emission areas of the first pixel and the second pixel surround first, second and third sides of the fourth light emission area;
one side of a first pixel circuit of a third pixel faces a side of the fourth light emission area without having a light emission area disposed between the one side and the side;
the first side extends along the first direction;
each of the second and third sides extends along a second direction different from the first direction; and
each of the one side and the side extends along the second direction.

22. The display device of claim 13, wherein:
the first light emission areas of the first and second pixels are configured to emit light having a same first color and are disposed adjacent to each other without a light emission area disposed between the first light emission areas;
the second light emission areas of the first and second pixels are configured to emit light having a same second color and are disposed adjacent to each other without a light emission area disposed between the second light emission areas; and
the fourth light emission area configured to emit light having another color is not adjacent to another light emission area configured to emit light having the same another color.
